(19) United States
(12) Patent Application Publication
(10) Pub. No.: US 2023/0420964 A1
(43) Pub. Date: Dec. 28, 2023

(54) CHARGING SYSTEM

(71) Applicant: SUBARU CORPORATION, Tokyo (JP)

(72) Inventors: Tatsuya ISHIBASHI, Tokyo (JP); Yusuke OKUBO, Tokyo (JP)

(73) Assignee: SUBARU CORPORATION, Tokyo (JP)

(21) Appl. No.: 18/209,681

(22) Filed: Jun. 14, 2023

(30) Foreign Application Priority Data
Jun. 24, 2022 (JP) 2022-101987

(51) Int. Cl. H02J 7/00; G01R 31/387; G01R 31/367; B60L 53/62

(52) U.S. Cl. CPC H02J 7/0047; G01R 31/387; G01R 31/367; B60L 53/62

(57) ABSTRACT

A charging system includes a charging control unit, a detector, an acquisition unit, a calculation unit, and an estimation unit. The charging control unit controls a charging operation performed from a power feeding system including a power storage device to a storage battery. The detector detects, multiple times, charging electric power supplied to the storage battery. The acquisition unit acquires pieces of charging data each including data indicating a temporal change in the charging electric power supplied from the power feeding system to the storage battery. The calculation unit calculates respective approximate curves of the pieces of charging data. The estimation unit estimates a power feedable time during which the power feeding system is able to feed power, based on the approximate curves calculated based on the pieces of charging data, by using values of the charging electric power detected by the detector.

### CROSS-REFERENCE TO RELATED APPLICATION

The present application claims priority from Japanese Patent Application No. 2022-101987 filed on Jun. 24, 2022, the entire contents of which are hereby incorporated by reference.

### BACKGROUND

The disclosure relates to a charging system that charges a storage battery of a vehicle.

Vehicles are often mounted with a storage battery. Japanese Unexamined Patent Application Publication No. 2017-221016 discloses a technique of estimating a dischargeable time based on a state of charge (SOC).

### SUMMARY

An aspect of the disclosure provides a charging system including a charging control unit, a detector, an acquisition unit, a calculation unit, and an estimation unit. The charging control unit is configured to control a charging operation performed from a power feeding system including a power storage device to a storage battery. The detector is configured to detect, multiple times, charging electric power supplied to the storage battery. The acquisition unit is configured to acquire pieces of charging data each including data indicating a temporal change in the charging electric power supplied from the power feeding system to the storage battery. The calculation unit is configured to calculate respective approximate curves of the pieces of charging data. The estimation unit is configured to estimate a power feedable time during which the power feeding system is able to feed power, based on the approximate curves calculated based on the pieces of charging data, by using values of the charging electric power detected by the detector.

An aspect of the disclosure provides a charging system including a detector and circuitry. The detector is configured to detect, multiple times, charging electric power supplied from a power feeding system including a power storage device to a storage battery. The circuitry is configured to: control a charging operation performed from the power feeding system to the storage battery; acquire pieces of charging data each including data indicating a temporal change in the charging electric power supplied from the power feeding system to the storage battery; calculate respective approximate curves of the pieces of charging data; and estimate a power feedable time during which the power feeding system is able to feed power, based on the approximate curves calculated based on the pieces of charging data, by using values of the charging electric power detected by the detector.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a block diagram illustrating a configuration example of a charging system according to one example embodiment of the disclosure.

FIG. 2 is a block diagram illustrating a configuration example of a device that receives electric power in a vehicle illustrated in FIG. 1.

FIG. 3 is an explanatory diagram illustrating an example of multiple pieces of charging data stored in a storage illustrated in FIG. 1.

FIG. 4 is a flowchart illustrating an operation example of the charging system illustrating in FIG. 1.

FIG. 5 is a flowchart illustrating an example of an estimation process illustrated in FIG. 4.

FIG. 6 is an explanatory diagram illustrating an example of the estimation process illustrated in FIG. 5.

FIG. 7 is another explanatory diagram illustrating an example of the estimation process illustrated in FIG. 5.

FIG. 8 is an explanatory diagram illustrating an example of the estimation process illustrated in FIG. 5.

FIG. 9 is another explanatory diagram illustrating an example of the estimation process illustrated in FIG. 5.

FIG. 10 is a flowchart illustrating an example of an estimation process according to a modification example of one example embodiment.

FIG. 11 is a block diagram illustrating a configuration example of a charging system according to one example embodiment of the disclosure.

FIG. 12 is a block diagram illustrating a configuration example of a device that receives electric power in a vehicle illustrated in FIG. 11.

FIG. 13 is a flowchart illustrating an example of an estimation process according to one example embodiment.

FIG. 14 is a block diagram illustrating a configuration example of a charging system according to one example embodiment of the disclosure.

FIG. 15 is a block diagram illustrating a configuration example of a device that receives electric power in a vehicle illustrated in FIG. 14.

FIG. 16 is a block diagram illustrating a configuration example of a server illustrated in FIG. 14.

FIG. 17 is an explanatory diagram illustrating an example of multiple pieces of charging data stored in a storage illustrated in FIG. 16.

FIG. 18 is a flowchart illustrating an example of an estimation process according to one example embodiment.

### DETAILED DESCRIPTION

Recent years have seen development of a vehicle, such as a plug-in electric vehicle or a plug-in hybrid vehicle, that is mounted with a storage battery and is able to have the storage battery charged at a power feeding station. Some of such power feeding stations include a storage battery for power feeding, and temporarily store electric power to be fed. When a SOC of the storage battery of the power feeding station is low, a time during which power is feedable to a vehicle is short. Accordingly, it is desired to calculate a time during which power is feedable by a simple method.

It is desirable to provide a charging system that makes it possible to calculate a time during which power is feedable by a simple method.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings.

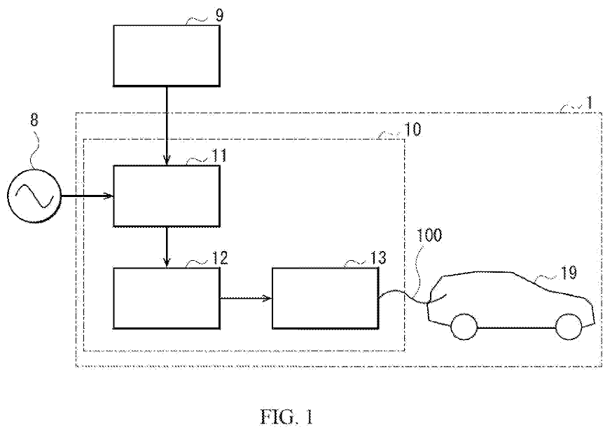

FIG. 1 illustrates a configuration example of a charging system 1 according to a first example embodiment. The charging system 1 may be configured to charge a storage battery of a vehicle 19. The charging system 1 may be coupled to a system power supply 8 and a solar power generation device 9. The system power supply 8 may be, for example, a so-called commercial power supply. The system power supply 8 may supply alternating-current electric power to the charging system 1. The solar power generation device 9 may generate direct-current electric power by power generation based on sunlight, and supply the direct-current electric power to the charging system 1. The charging system 1 may include a power feeding station 10 and the vehicle 19.

The power feeding station 10 may feed direct-current electric power to the vehicle 19. The power feeding station 10 may include a power conditioner 11, a power storage device 12, and a power feeding device 13.

The power conditioner 11 may convert the alternating-current electric power supplied from the system power supply 8 into direct-current electric power by AC/DC conversion, and supply the converted direct-current electric power to the power storage device 12. In addition, the power conditioner 11 may convert the direct-current electric power supplied from the solar power generation device 9 by DC/DC conversion, and supply the converted direct-current electric power to the power storage device 12.

The power storage device 12 may include a storage battery. The power storage device 12 may temporarily store the direct-current electric power supplied from the power conditioner 11. The power storage device 12 may supply, to the power feeding device 13, the direct-current electric power supplied from the power conditioner 11 and the direct-current electric power stored in the power storage device 12.

The power feeding device 13 may supply the direct-current electric power supplied from the power storage device 12 to the vehicle 19 via a power feeding cable 100.

As described above, the power feeding station 10 may include the power storage device 12, and supply the direct-current electric power stored in the power storage device 12 to the vehicle 19. Thus, for example, even if electric power supplied from the system power supply 8 and the solar power generation device 9 is insufficient, the power feeding station 10 is able to effectively supply direct-current electric power to the vehicle 19 by supplementarily using the direct-current electric power stored in the power storage device 12. For example, when feeding power to multiple vehicles at the same time, electric power supplied from the system power supply 8 and the solar power generation device 9 can be insufficient. Even in this case, the power feeding station 10 is able to effectively supply direct-current electric power to the vehicle 19, by using both of electric power supplied from the system power supply 8 and the solar power generation device 9 and electric power stored in the power storage device 12.

The vehicle 19 may be a vehicle such as an automobile. The vehicle 19 may be a plug-in electric vehicle in this example. Without being limited thereto, the vehicle 19 may be a plug-in hybrid vehicle.

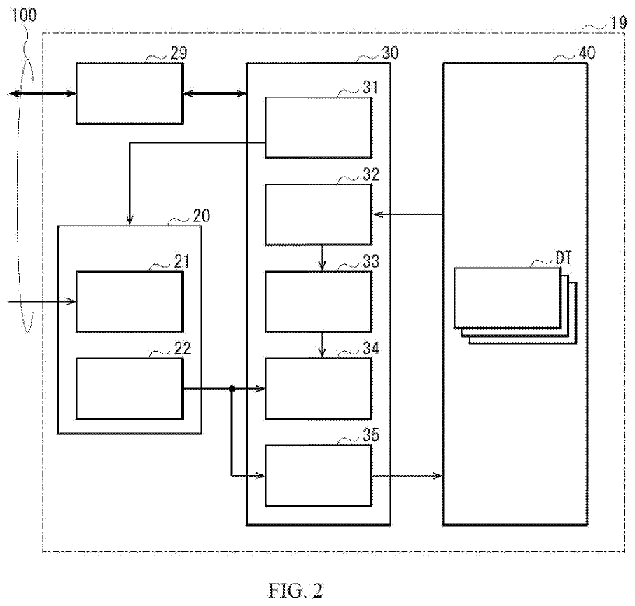

FIG. 2 illustrates a configuration example of a device, in the vehicle 19, that receives electric power supplied from the power feeding station 10. The vehicle 19 may include a storage battery unit 20, a communicator 29, a processor 30, and a storage 40.

The storage battery unit 20 may include a storage battery 21 and an electric power sensor 22. The storage battery 21 may store direct-current electric power supplied from the power feeding station 10 via the power feeding cable 100, and supply the stored electric power to an unillustrated inverter of the vehicle 19. In the vehicle 19, the inverter may drive a motor to generate driving force that allows the vehicle 19 to travel. The electric power sensor 22 detects charging electric power supplied from the power feeding station 10 to the storage battery 21. The storage battery unit 20 may perform a charging operation to the storage battery 21, based on a control signal from the processor 30.

The communicator 29 may communicate with the power feeding station 10 via the power feeding cable 100. The communicator 29 may acquire a power feeding station identifier for identification of the power feeding station 10, for example, by communicating with the power feeding station 10.

The processor 30 may control a power receiving operation of the storage battery unit 20. The processor 30 may include, for example, one or more microcontrollers and one or more memories. The processor 30 may include a charging control unit 31, a charging data acquisition unit 32, an approximate curve calculation unit 33, an estimation unit 34, and a charging data registration unit 35.

The charging control unit 31 controls the charging operation performed from the power feeding station 10 to the storage battery 21 of the storage battery unit 20.

The charging data acquisition unit 32 may acquire charging data DT from the storage 40.

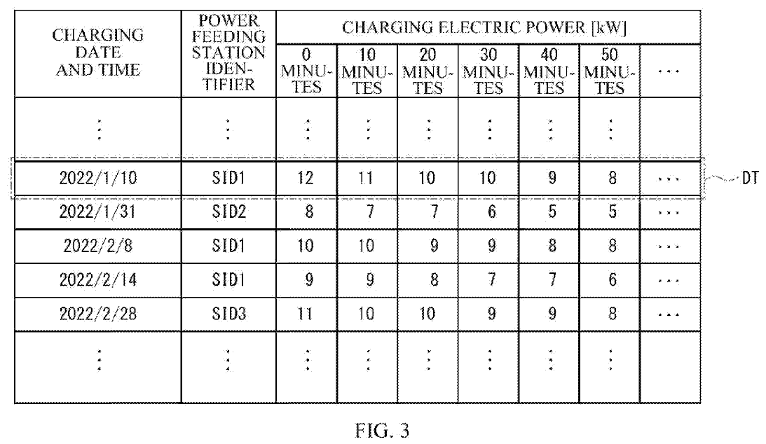

FIG. 3 illustrates an example of multiple pieces of charging data DT stored in the storage 40. The charging data DT may include a charging date and time when the vehicle 19 has performed the charging operation, the power feeding station identifier of the power feeding station 10 that has fed power to the vehicle 19, and data regarding a temporal change in the charging electric power. In this example, the data regarding the temporal change in the charging electric power may include data on the charging electric power at the start of charging and for every 10 minutes after the start of charging.

For example, the power feeding device 13 may feed power to the vehicle 19 with feeding electric power corresponding to a SOC of the power storage device 12. Accordingly, the charging electric power supplied to the vehicle 19 is high when the SOC of the power storage device 12 is high, and low when the SOC of the power storage device 12 is low. The SOC of the power storage device 12 gradually decreases with continuation of power feeding, and the feeding electric power thus gradually decreases over time. Accordingly, the charging electric power supplied to the vehicle 19 gradually decreases as charging time elapses.

Note that, although the power feeding station 10 includes the power storage device 12 in this example, there can also be a power feeding station including no power storage device. Such a power feeding station may be supplied with sufficient electric power from the system power supply 8 at all times. This power feeding station is able to, for example, when feeding power to the vehicle 19, keep the feeding electric power at predetermined electric power. This allows the charging electric power supplied to the vehicle 19 to be kept at a constant value.

The charging data acquisition unit 32 may acquire, out of the multiple pieces of charging data DT stored in the storage 40, pieces of charging data DT including the same power feeding station identifier as the power feeding station identifier of the power feeding station 10 feeding power to the vehicle 19. The charging data acquisition unit 32 may supply the acquired pieces of charging data DT to the approximate curve calculation unit 33.

The approximate curve calculation unit 33 calculates respective approximate curves of the pieces of charging data DT acquired by the charging data acquisition unit 32.

The estimation unit 34 estimates a time during which the power feeding station 10 is able to feed power, based on the approximate curves calculated by the approximate curve calculation unit 33, by using data on received electric power supplied from the electric power sensor 22. The time during which the power feeding station 10 is able to feed power is also referred to as a power feedable time T. The power feedable time T may be presented to a driver who drives the vehicle 19, for example, by an unillustrated display device provided in the vehicle 19.

The charging data registration unit 35 may generate charging data DT based on the data on the received electric power supplied from the electric power sensor 22, and register the generated charging data DT in the storage 40.

The storage 40 may be a nonvolatile storage device. For example, the storage 40 may include a semiconductor memory. The storage 40 may hold multiple pieces of charging data DT.

In one embodiment, the power feeding station 10 may serve as a “power feeding system”. In one embodiment, the power storage device 12 may serve as a “power storage device”. In one embodiment, the storage battery 21 may serve as a “storage battery”. In one embodiment, the charging control unit 31 may serve as a “charging control unit”. In one embodiment, the electric power sensor 22 may serve as a “detector”. In one embodiment, the charging data acquisition unit 32 may serve as an “acquisition unit”. In one embodiment, the approximate curve calculation unit 33 may serve as a “calculation unit”. In one embodiment, the estimation unit 34 may serve as an “estimation unit”. In one embodiment, the storage 40 may serve as a “storage”. In one embodiment, the charging data registration unit 35 may serve as a “registration unit”.

Next, operations and workings of the charging system 1 according to the example embodiment are described.

First, operation of the charging system 1 is described with reference to FIGS. 1 and 2. The power conditioner 11 may convert the alternating-current electric power supplied from the system power supply 8 into direct-current electric power by AC/DC conversion, and supply the converted direct-current electric power to the power storage device 12. In addition, the power conditioner 11 may convert the direct-current electric power supplied from the solar power generation device 9 by DC/DC conversion, and supply the converted direct-current electric power to the power storage device 12. The power storage device 12 may temporarily store the direct-current electric power supplied from the power conditioner 11. The power storage device 12 may supply, to the power feeding device 13, the direct-current electric power supplied from the power conditioner 11 and the direct-current electric power stored in the power storage device 12. The power feeding device 13 may supply the direct-current electric power supplied from the power storage device 12 to the vehicle 19 via the power feeding cable 100.

In the vehicle 19, the storage battery 21 of the storage battery unit 20 may store direct-current electric power supplied from the power feeding station 10 via the power feeding cable 100, and supply the stored electric power to the unillustrated inverter of the vehicle 19. The electric power sensor 22 detects the charging electric power supplied from the power feeding station 10 to the storage battery 21. The communicator 29 may acquire the power feeding station identifier, which is an identifier specific to the power feeding station 10, by communicating with the power feeding station 10 via the power feeding cable 100. The charging control unit 31 of the processor 30 controls the charging operation performed from the power feeding station 10 to the storage battery 21 of the storage battery unit 20. The charging data acquisition unit 32 may acquire, out of the multiple pieces of charging data DT stored in the storage 40, pieces of charging data DT including the same power feeding station identifier as the power feeding station identifier of the power feeding station 10 feeding power to the vehicle 19. The approximate curve calculation unit 33 calculates respective approximate curves of the pieces of charging data DT acquired by the charging data acquisition unit 32. The estimation unit 34 estimates the time during which the power feeding station 10 is able to feed power (i.e., the power feedable time T), based on the approximate curves calculated by the approximate curve calculation unit 33, by using data on the received electric power supplied from the electric power sensor 22. The charging data registration unit 35 may generate charging data DT, based on the data on the received electric power supplied from the electric power sensor 22, and register the generated charging data DT in the storage 40. The storage 40 may hold multiple pieces of charging data DT.

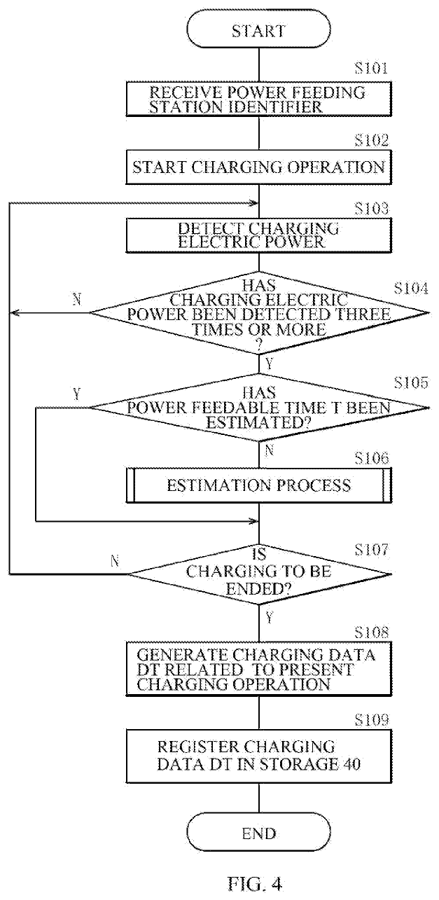

FIG. 4 illustrates an operation example of the vehicle 19 when the storage battery 21 of the vehicle 19 is charged based on electric power supplied from the power feeding station 10. This flow may start, for example, by the driver setting a plug of the power feeding cable 100 into an inlet of the vehicle 19.

First, the communicator 29 of the vehicle 19 may receive a power feeding station identifier by communicating with the power feeding device 13 of the power feeding station 10 (step S101). The communicator 29 may supply the power feeding station identifier to the processor 30.

Thereafter, the charging control unit 31 may start the charging operation performed to the storage battery 21 of the storage battery unit 20 (step S102). Thus, direct-current electric power supplied from the power feeding station 10 may start to be stored in the storage battery 21 of the storage battery unit 20.

Thereafter, the electric power sensor 22 of the storage battery unit 20 may detect the charging electric power supplied to the storage battery 21 (step S103). The electric power sensor 22 may supply a detection result thus obtained to the processor 30.

Thereafter, the processor 30 may check whether the electric power sensor 22 has detected the charging electric power three times or more (step S104). If the electric power sensor 22 has not yet detected the charging electric power three times or more (“N” in step S104), the process may return to step S103. Thus, the processor 30 may repeat steps S103 and S104 until the electric power sensor 22 detects the charging electric power three times. In this example, the processor 30 may perform control to cause the electric power sensor 22 to detect the received electric power at intervals of five minutes. Thus, the electric power sensor 22 may detect the charging electric power at the start of charging, five minutes after the start of charging, and 10 minutes after the start of charging.

If the electric power sensor 22 has already detected the charging electric power three times or more in step S104 (“Y” in step S104), the processor 30 may check whether the power feedable time T has been estimated (step S105). If the processor 30 has already estimated the power feedable time T (“Y” in step S105), the process may proceed to step S107.

If the processor 30 has not yet estimated the power feedable time T in step S105 (“N” in step S105), the processor 30 may perform an estimation process of estimating the power feedable time T (step S106).

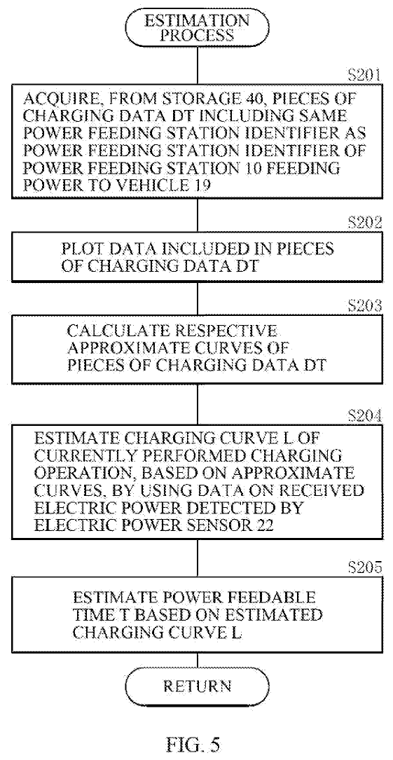

FIG. 5 illustrates an example of a subroutine of the estimation process of estimating the power feedable time T.

First, the charging data acquisition unit 32 of the processor 30 may acquire, from the storage 40, pieces of charging data DT including the same power feeding station identifier as the power feeding station identifier, acquired in step S101, of the power feeding station 10 currently feeding power to the vehicle 19, out of the stored multiple pieces of charging data DT (step S201). In other words, as illustrated in FIG. 3, the storage 40 may hold multiple pieces of charging data DT related to various power feeding stations that have fed power to the vehicle 19 in the past. The charging data acquisition unit 32 may acquire, out of the multiple pieces of charging data DT, pieces of charging data DT related to the power feeding station 10 currently feeding power.

Thereafter, the charging data acquisition unit 32 may plot the data on the charging electric power included in the pieces of charging data DT acquired in step S201 (step S202).

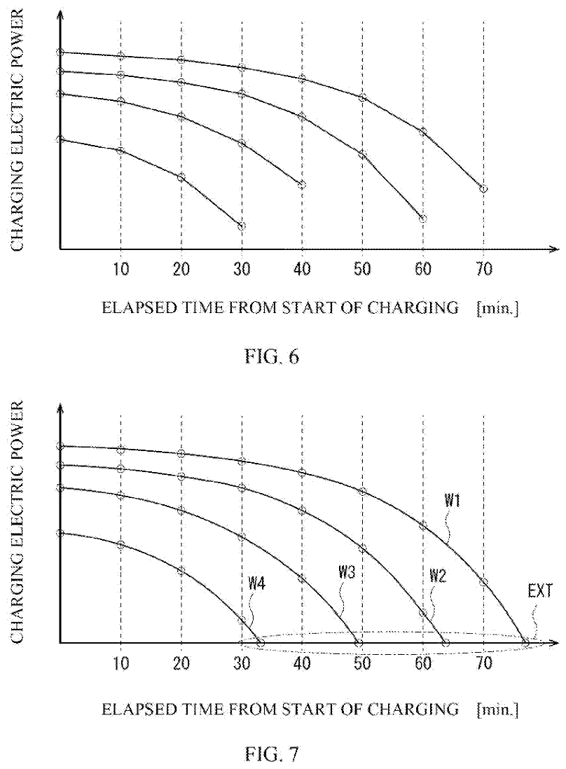

FIG. 6 illustrates a result of plotting the data on the charging electric power. The horizontal axis represents elapsed time from the start of charging, and the vertical axis represents the charging electric power. In this example, FIG. 6 illustrates the temporal change in the charging electric power related to four pieces of charging data DT.

Thereafter, the approximate curve calculation unit 33 may calculate respective approximate curves of the pieces of charging data DT plotted in step S202 (step S203). In one example, the approximate curve calculation unit 33 may calculate the approximate curve, for example, by performing fitting using a function such as a quadratic function, based on the data on the temporal change in the charging electric power included in the charging data DT.

FIG. 7 illustrates an example of the respective approximate curves of the pieces of charging data DT illustrated in FIG. 6. In this example, the approximate curve calculation unit 33 may calculate four approximate curves W1 to W4, based on the data on the temporal change in the charging electric power included in the four pieces of charging data DT. The approximate curve calculation unit 33 may calculate, by extrapolation, a point where the charging electric power becomes zero (i.e., an extrapolation point EXT) on each of the approximate curves W1 to W4.

Thereafter, the estimation unit 34 may estimate a charging curve L of the currently performed charging operation, based on the approximate curves calculated by the approximate curve calculation unit 33, by using the data on the received electric power detected by the electric power sensor 22 (step S204).

FIG. 8 illustrates an example of the operation of the estimation unit 34 in step S204. The estimation unit 34 may horizontally flip each of the approximate curves calculated by the approximate curve calculation unit 33, and perform replotting with respect to the extrapolation point EXT. The estimation unit 34 may estimate the charging curve L in which the data on the received electric power (received electric power P0, P1, and P2) detected by the electric power sensor 22 in step S103 lie on the curve. In this example, the received electric power P0 is the charging electric power at the start of charging, the received electric power P1 is the charging electric power five minutes after the start of charging, and the received electric power P2 is the charging electric power 10 minutes after the start of charging. In a horizontal axis direction in FIG. 8, a point representing the received electric power P1 may be positioned on the left side relative to a point representing the received electric power P0 by five minutes, and a point representing the received electric power P2 may be positioned on the left side relative to the point representing the received electric power P1 by five minutes. As illustrated in FIG. 8, within a range of the received electric power P0 to P2, the approximate curve positioned on the right side has a smaller gradient, and the approximate curve positioned on the left side has a larger gradient. The estimation unit 34 may estimate the charging curve L in which the data on the received electric power P0, P1, and P2 lie on the curve. In this example, these three points lie on the line of the approximate curve W1. Accordingly, in this example, the approximate curve W1 is the charging curve L of the currently performed charging operation. It is estimated that the charging electric power subsequently decreases along the charging curve L.

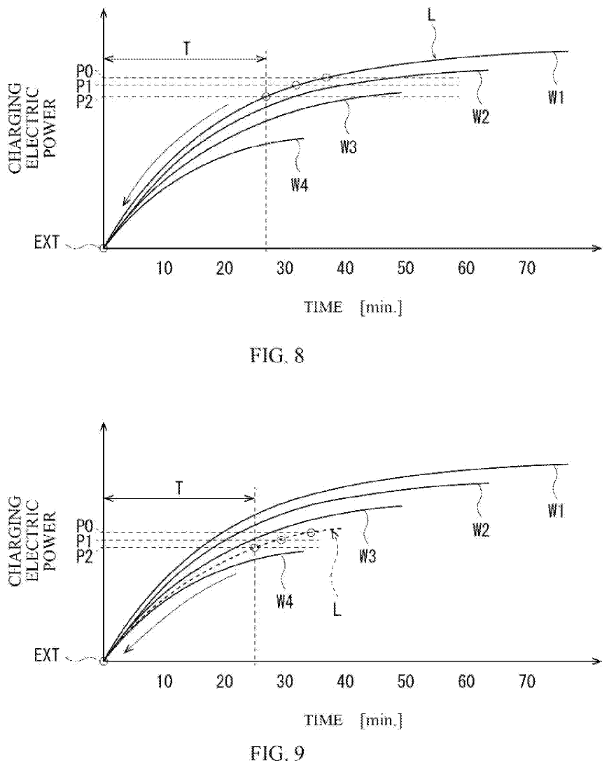

FIG. 9 illustrates another example of the operation of the estimation unit 34 in step S204. In this example, values of the received electric power P0, P1, and P2 are lower than in the example in FIG. 8. The estimation unit 34 may estimate the charging curve L in which the data on such received electric power P0, P1, and P2 lie on the curve. In this example, the estimation unit 34 may estimate, based on the approximate curves W3 and W4, the charging curve L positioned between these curves. The charging curve L estimated in this manner may be a curve passing through the origin of the graph in FIG. 9 and expressible by, for example, a function such as a quadratic function. It is estimated that the charging electric power subsequently decreases along the charging curve L.

In this manner, the estimation unit 34 may estimate the charging curve L of the currently performed charging operation.

Thereafter, the estimation unit 34 may estimate the power feedable time T, based on the charging curve L estimated in step S204 (step S205). As illustrated in FIG. 4, the subroutine of the estimation process may be performed immediately after the electric power sensor 22 detects the received electric power three times. The received electric power P2 may be the detection result for the third time obtained by the electric power sensor 22. Accordingly, as illustrated in FIGS. 8 and 9, the estimation unit 34 may estimate the power feedable time T, based on a time from the point representing the received electric power P2 on the charging curve L to the origin of the graph.

This may be the end of the subroutine of the estimation process. For example, the unillustrated display device of the vehicle 19 may present the estimated power feedable time T to the driver.

Thereafter, as illustrated in FIG. 4, the charging control unit 31 may check whether charging is to be ended (step S107). In one example, the charging control unit 31 may check whether charging is to be ended, for example, by checking whether a predetermined time set in advance has elapsed from the start of charging. In another example, the charging control unit 31 may check whether charging is to be ended, for example, by checking whether a SOC of the storage battery 21 of the vehicle 19 has reached a predetermined level. In another example, the charging control unit 31 may check whether charging is to be ended, for example, by checking whether the driver has performed a charging ending operation. If charging is not to be ended (“N” in step S107), the process may return to step S103. Thereafter, the electric power sensor 22 may detect the charging electric power, for example, each time 10 minutes elapses in step S103, until charging ends.

If charging is to be ended in step S107 (“Y” in step S107), the charging data registration unit 35 may generate charging data DT related to the present charging operation (step S108). In one example, the charging data registration unit 35 may generate charging data DT including the date and time when the present charging operation has been started, the power feeding station identifier received in step S101, and the data on the charging electric power for every 10 minutes detected in step S103.

The charging data registration unit 35 may register the charging data DT in the storage 40 (step S109).

Thereafter, this process may end.

As described above, the charging system 1 includes the charging control unit 31, the electric power sensor 22, the charging data acquisition unit 32, the approximate curve calculation unit 33, and the estimation unit 34. The charging control unit 31 is configured to control the charging operation performed from the power feeding station 10 including the power storage device 12 to the storage battery 21. The electric power sensor 22 is configured to detect, multiple times, the charging electric power supplied to the storage battery 21. The charging data acquisition unit 32 is configured to acquire pieces of charging data DT each including data indicating a temporal change in the charging electric power supplied from the power feeding station 10 to the storage battery 21. The approximate curve calculation unit 33 is configured to calculate respective approximate curves of the pieces of charging data DT. The estimation unit 34 is configured to estimate the power feedable time T during which the power feeding station 10 is able to feed power, based on the approximate curves calculated based on the pieces of charging data DT, by using values of the received electric power detected by the electric power sensor 22. For example, the estimation unit 34 may estimate the charging curve L indicating a subsequent change in the charging electric power, based on the approximate curves calculated based on the pieces of charging data DT, by using the values of the received electric power detected by the electric power sensor 22, and estimate the power feedable time based on the charging curve L. Thus, the charging system 1 makes it possible to calculate the time during which power is feedable by a simple method. Consequently, the charging system 1 makes it possible to enhance, for example, convenience for the driver.

In other words, a power feeding station often does not supply a vehicle with information regarding a SOC of a storage battery provided in the power feeding station. In this case, the vehicle is unable to find the SOC of the storage battery provided in the power feeding station, thus being unable to find how much electric power the power feeding station is able to feed. Hence, for example, while charging a storage battery of the vehicle, the SOC of the storage battery of the power feeding station can become sufficiently low, and the power feeding station can forcedly stop power feeding. In addition, for example, when the power feeding station forcedly stops power feeding immediately after the driver performs a payment operation for charging, paid charge can be wasted.

In contrast, in the charging system 1, the processor 30 of the vehicle 19 is able to estimate the power feedable time T. This, for example, allows the driver to find whether the power feeding station 10 is able to perform power feeding sufficiently. For example, when the power feeding station 10 is unable to perform power feeding sufficiently, the driver is able to head for a nearby other power feeding station 10. For example, when the power feeding station 10 is able to perform power feeding sufficiently, the driver is able to run another errand while the storage battery 21 is being charged, which makes it possible to use time efficiently. In addition, for example, the driver is able to determine timing of performing a payment operation for charging based on the power feedable time T, which makes it possible to prevent paid charge from being wasted.

In the charging system 1, the charging data acquisition unit 32 acquires the pieces of charging data DT including the data indicating the temporal change in the charging electric power supplied from the power feeding station 10 to the storage battery 21. In other words, the pieces of charging data DT may include data regarding a temporal change in the charging electric power supplied from one power feeding station 10 to the storage battery 21 of the vehicle 19, i.e., the own vehicle. In the charging system 1, the power feedable time T is estimated based on the pieces of charging data DT. Thus, for example, neither charging data DT related to various power feeding stations nor charging data DT related to various vehicles is used. This makes it possible to enhance estimation accuracy of the power feedable time T.

In the charging system 1, the electric power sensor 22 may detect the received electric power three times. The estimation unit 34 may estimate the charging curve L by using the data on the received electric power for the three times, and estimate the power feedable time T based on the charging curve L. Thus, the charging system 1 makes it possible to enhance the estimation accuracy of the power feedable time T. In other words, the charging electric power tends to linearly change when the SOC of the power storage device 12 of the power feeding station 10 is high, but when the SOC of the power storage device 12 becomes low, the charging electric power abruptly decreases instead of linearly decreasing, for example, as illustrated in FIG. 7. The estimation unit 34 may estimate the charging curve L by using the data on the received electric power for the three times, which makes it possible to estimate the charging curve L with higher accuracy by using the abrupt change in the charging electric power. Consequently, the charging system 1 makes it possible to enhance the estimation accuracy of the power feedable time T.

As described above, in the example embodiment, the charging control unit, the electric power sensor, the charging data acquisition unit, the approximate curve calculation unit, and the estimation unit are provided. The charging control unit is configured to control the charging operation performed from the power feeding station including the power storage device to the storage battery. The electric power sensor is configured to detect, multiple times, the charging electric power supplied to the storage battery. The charging data acquisition unit is configured to acquire pieces of charging data each including data indicating a temporal change in the charging electric power supplied from the power feeding station to the storage battery. The approximate curve calculation unit is configured to calculate respective approximate curves of the pieces of charging data. The estimation unit is configured to estimate the power feedable time during which the power feeding station is able to feed power, based on the approximate curves calculated based on the pieces of charging data, by using values of the received electric power detected by the electric power sensor. For example, the estimation unit may estimate the charging curve indicating a subsequent change in the charging electric power, based on the approximate curves calculated based on the pieces of charging data, by using the values of the received electric power detected by the electric power sensor, and estimate the power feedable time based on the charging curve. This makes it possible to calculate the time during which power is feedable by a simple method.

In the first example embodiment, the estimation unit 34 may estimate the power feedable time T based on the charging curve L, but this is non-limiting. For example, the estimation unit 34 may further estimate the SOC of the power storage device 12 in the power feeding station 10, based on the charging curve L. In one example, the estimation unit 34 may divide the charging electric power of the charging curve L (e.g., FIG. 8) by a power feeding voltage, which is a predetermined value, to thereby obtain a charging current curve. The estimation unit 34 may integrate a charging current in the charging current curve with respect to the power feedable time T, to thereby calculate remaining storage battery power of the power storage device 12. In this manner, the estimation unit 34 may estimate the SOC of the power storage device 12 in the power feeding station 10.

In the first example embodiment, as illustrated in FIG. 5, the processor 30 may estimate the power feedable time T based on the pieces of charging data DT including the same power feeding station identifier as the power feeding station identifier of the power feeding station 10 feeding power to the vehicle 19, but this is non-limiting. Modification Example 1-2 is described in detail below.

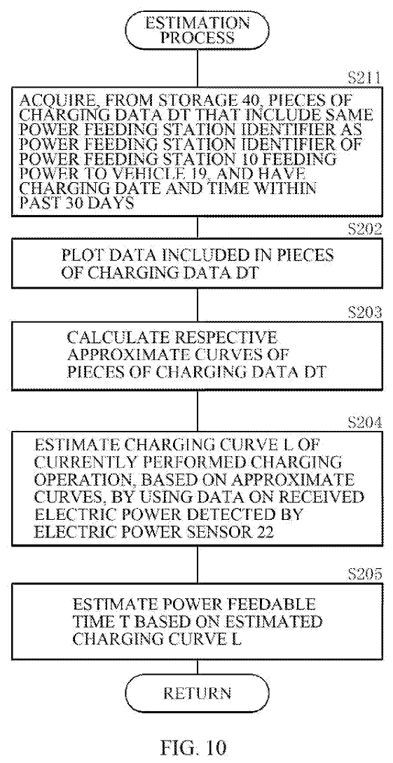

FIG. 10 illustrates an example of an estimation process according to Modification Example 1-2.

First, the charging data acquisition unit 32 may acquire, from the storage 40, pieces of charging data DT that include the same power feeding station identifier as the power feeding station identifier of the power feeding station 10 feeding power to the vehicle 19, and have a charging date and time within the past 30 days, out of the stored multiple pieces of charging data DT (step S211). In other words, the storage 40 may hold multiple pieces of charging data DT registered in a past long period. The charging data acquisition unit 32 may acquire, out of the multiple pieces of charging data DT, pieces of charging data DT having a charging date and time within the past 30 days.

Thereafter, the charging data acquisition unit 32 may plot the data on the charging electric power included in the pieces of charging data DT acquired in step S211 (step S202). The approximate curve calculation unit 33 may calculate respective approximate curves of the pieces of charging data DT plotted in step S202 (step S203). The estimation unit 34 may estimate the charging curve L of the currently performed charging operation, based on the approximate curves calculated by the approximate curve calculation unit 33, by using the data on the received electric power detected by the electric power sensor 22 (step S204). The estimation unit 34 may estimate the power feedable time T, based on the charging curve L estimated in step S204 (step S205).

In the charging system 1 according to Modification Example 1-2, the power feedable time T may be estimated based on the pieces of charging data DT that include the same power feeding station identifier as the power feeding station identifier of the power feeding station feeding power to the vehicle 19, and have been generated within a predetermined period (e.g., within the past 30 days). This makes it possible to enhance the estimation accuracy of the power feedable time T. In other words, a characteristic of the power storage device 12 of the power feeding station 10 can change over time. In the charging system 1 according to Modification Example 1-2, the power feedable time T may be estimated based on the charging data DT generated within the predetermined period (within the past 30 days), which makes it possible to suppress the influence of the change over time in the characteristic of the power storage device 12 on the estimation accuracy of the power feedable time T. This makes it possible to enhance the estimation accuracy of the power feedable time T.

Two or more of the modification examples described above may be employed in combination.

Next, a charging system 2 according to a second example embodiment is described. In the example embodiment, a vehicle may estimate the power feedable time T by using, in addition to the own charging data DT, charging data DT supplied from another vehicle by vehicle-to-vehicle communication. Note that components substantially the same as those in the charging system 1 according to the first example embodiment are denoted with the same reference numerals to avoid any redundant description.

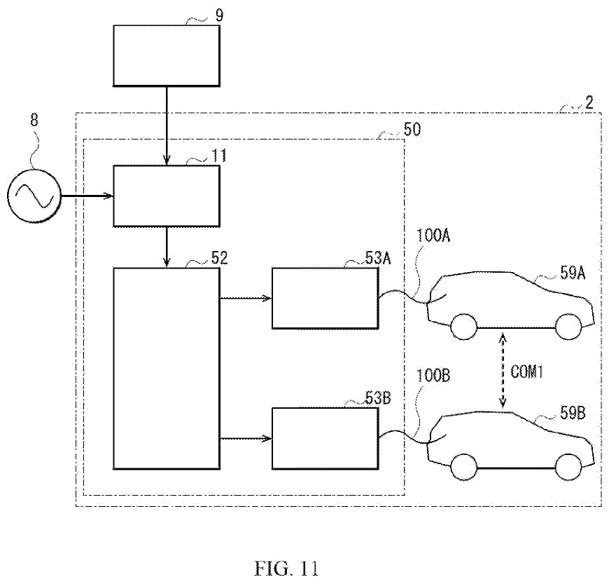

FIG. 11 illustrates a configuration example of the charging system 2 according to the second example embodiment. The charging system 2 may include a power feeding station and vehicles 59A and 59B.

The power feeding station 50 may include a power storage device 52 and power feeding devices 53A and 53B.

The power storage device 52 may include a storage battery, and may temporarily store the direct-current electric power supplied from the power conditioner 11, as with the power storage device 12 according to the first example embodiment. The power storage device 52 may supply, to the power feeding devices 53A and 53B, the direct-current electric power supplied from the power conditioner 11 and the direct-current electric power stored in the power storage device 52.

The power feeding device 53A may supply the direct-current electric power supplied from the power storage device 52 to the vehicle 59A via a power feeding cable 100A. The power feeding device 53B may supply the direct-current electric power supplied from the power storage device 52 to the vehicle 59B via a power feeding cable 100B.

The vehicles 59A and 59B may each be a plug-in electric vehicle in this example, as with the vehicle 19 according to the first example embodiment. The vehicles 59A and 59B may be able to perform vehicle-to-vehicle communication COM1 with each other.

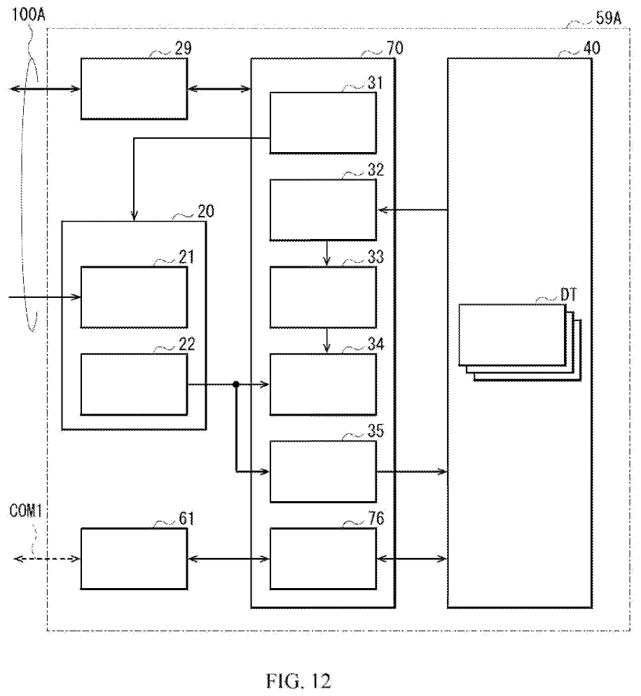

FIG. 12 illustrates a configuration example of a device, in the vehicle 59A, that receives electric power supplied from the power feeding station 50. Note that the same applies to the vehicle 59B. The vehicle 59A may include a vehicle-to-vehicle communicator 61 and a processor 70.

The vehicle-to-vehicle communicator 61 may perform the vehicle-to-vehicle communication COM1 with another vehicle near the vehicle 59A. The vehicle-to-vehicle communicator 61 may transmit and receive charging data DT and a vehicle type identifier for identification of a vehicle type, by performing the vehicle-to-vehicle communication COM1 with the nearby other vehicle.

The processor 70 may include a charging data management unit 76. The charging data management unit 76 may cause the vehicle-to-vehicle communicator 61 to transmit charging data DT stored in the storage 40, or store charging data DT received by the vehicle-to-vehicle communicator 61 in the storage 40.

Operation of the vehicle 59A when the storage battery 21 of the vehicle 59A is charged based on electric power supplied from the power feeding station 50 may be similar to the case in the first example embodiment (FIG. 4). An estimation process of estimating the power feedable time T (step S106 in FIG. 4) is described below. In this example, the vehicle 59B may be, for example, coupled to the power feeding device 53B via the power feeding cable 100B, and performing a charging operation to the storage battery 21.

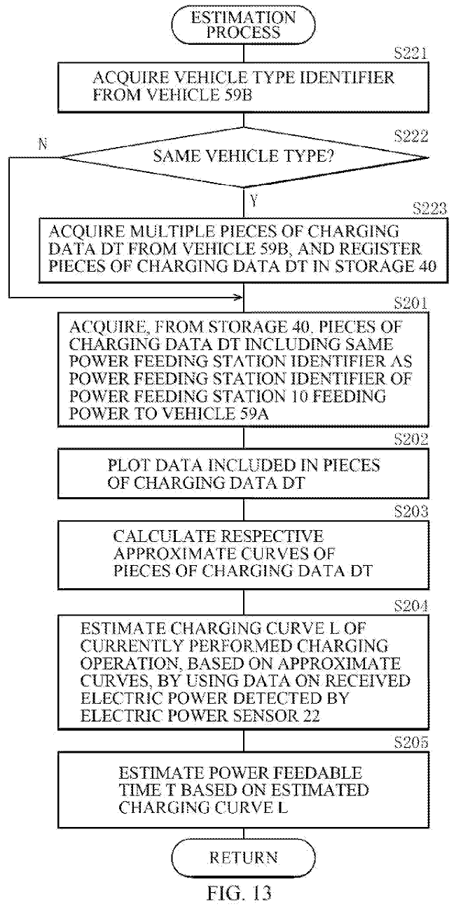

FIG. 13 illustrates an example of a subroutine of the estimation process of estimating the power feedable time T in the processor 70 of the vehicle 59A.

First, based on an instruction from the charging data management unit 76, the vehicle-to-vehicle communicator 61 may acquire the vehicle type identifier of the vehicle 59B, by performing the vehicle-to-vehicle communication COM1 with the vehicle 59B (step S221).

Thereafter, the charging data management unit 76 may check, based on the vehicle type identifier of the vehicle 59B, whether the vehicle type of the vehicle 59A and the vehicle type of the vehicle 59B are the same (step S222). If the vehicle types are not the same (“N” in step S222), the process may proceed to step S201.

If the vehicle type of the vehicle 59A and the vehicle type of the vehicle 59B are the same in step S222 (“Y” in step S222), the vehicle-to-vehicle communicator 61 may, based on an instruction from the charging data management unit 76, acquire multiple pieces of charging data DT stored in the storage 40 of the vehicle 59B, by performing the vehicle-to-vehicle communication COM1 with the vehicle 59B, and register the pieces of charging data DT in the storage 40 (step S223). Thus, charging data DT related to the vehicle 59A and charging data DT related to the vehicle 59B may be stored in the storage 40 of the vehicle 59A.

The charging data acquisition unit 32 may acquire, from the storage 40, pieces of charging data DT including the same power feeding station identifier as the power feeding station identifier of the power feeding station 50 feeding power to the vehicle 59A, out of the stored multiple pieces of charging data DT (step S201). Thereafter, the charging data acquisition unit 32 may plot the data on the charging electric power included in the pieces of charging data DT acquired in step S201 (step S202). The approximate curve calculation unit 33 may calculate respective approximate curves of the pieces of charging data DT plotted in step S202 (step S203). The estimation unit 34 may estimate the charging curve L of the currently performed charging operation, based on the approximate curves calculated by the approximate curve calculation unit 33, by using the data on the received electric power detected by the electric power sensor 22 (step S204). The estimation unit 34 may estimate the power feedable time T, based on the charging curve L estimated in step S204 (step S205).

In this manner, in the charging system 2, when the vehicle type of the vehicle 59A and the vehicle type of the vehicle 59B are the same, the power feedable time T may be estimated based on the pieces of charging data DT including data indicating a temporal change in the charging electric power supplied from the power feeding station 50 to the storage battery 21 of the vehicle 59A, and data indicating a temporal change in the charging electric power supplied from the power feeding station 50 to the storage battery 21 of the vehicle 59B. This makes it possible to enhance the estimation accuracy of the power feedable time T. In other words, when the vehicle type of the vehicle 59A and the vehicle type of the vehicle 59B are the same, the storage battery 21 of the vehicle 59A and the storage battery 21 of the vehicle 59B are of the same type as each other. In this case, the charging operation related to the vehicle 59A and the charging operation related to the vehicle 59B exhibit the same characteristic as each other. In the charging system 2, the power feedable time T may be estimated based also on pieces of charging data DT generated by the vehicle 59B, in addition to pieces of charging data DT generated by the vehicle 59A. This increases, in the charging system 2, the number of pieces of the charging data DT to be used in estimating the power feedable time T, which makes it possible to enhance the estimation accuracy of the power feedable time T.

As described above, in the example embodiment, the power feedable time may be estimated based on the pieces of charging data including data indicating a temporal change in the charging electric power supplied from the power feeding station to the storage battery of the vehicle 59A, and data indicating a temporal change in the charging electric power supplied from the power feeding station to the storage battery of the vehicle 59B, which makes it possible to enhance the estimation accuracy of the power feedable time. Other effects may be similar to those in the first example embodiment.

The modification examples of the first example embodiment may be applied to the charging system 2 according to the second example embodiment.

Next, a charging system 3 according to a third example embodiment is described. In the example embodiment, a server may estimate the power feedable time T by using charging data DT on multiple vehicles. Note that components substantially the same as those in the charging system 1 according to the first example embodiment are denoted with the same reference numerals to avoid any redundant description.

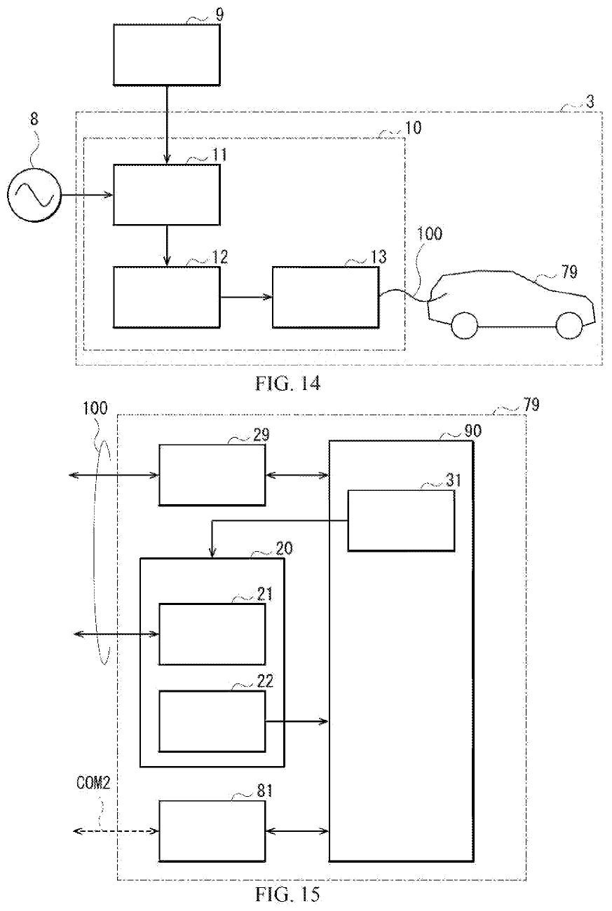

FIG. 14 illustrates a configuration example of the charging system 3 according to the third example embodiment. The charging system 3 may include the power feeding station 10, a vehicle 79, and a server 110. The vehicle 79 may perform communication COM2 with the server 110.

FIG. 15 illustrates a configuration example of a device, in the vehicle 79, that receives electric power supplied from the power feeding station 10. The vehicle 79 may include the storage battery unit 20, the communicator 29, a wireless communicator 81, and a processor 90. The wireless communicator 81 may, for example, communicate with an unillustrated base station by means of wireless communication such as Long-Term Evolution (LTE), 5G, or a wireless local area network (LAN), to thereby perform the communication COM2 with the server 110 via the base station. The processor 90 may include the charging control unit 31.

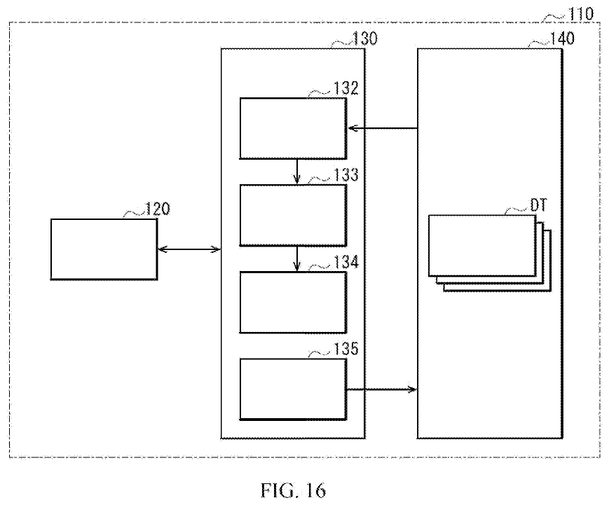

FIG. 16 illustrates a configuration example of the server 110. The server 110 may include a communicator 120, a processor 130, and a storage 140.

The communicator 120 may perform the communication COM2 with the vehicle 79, via the base station for wireless communication.

The processor 130 may perform various processes in the server 110. The processor 130 may include, for example, one or more microcontrollers and one or more memories. The processor 130 may include a charging data acquisition unit 132, an approximate curve calculation unit 133, an estimation unit 134, and a charging data registration unit 135.

The charging data acquisition unit 132 may acquire charging data DT from the storage 140, as with the charging data acquisition unit 32 according to the first example embodiment.

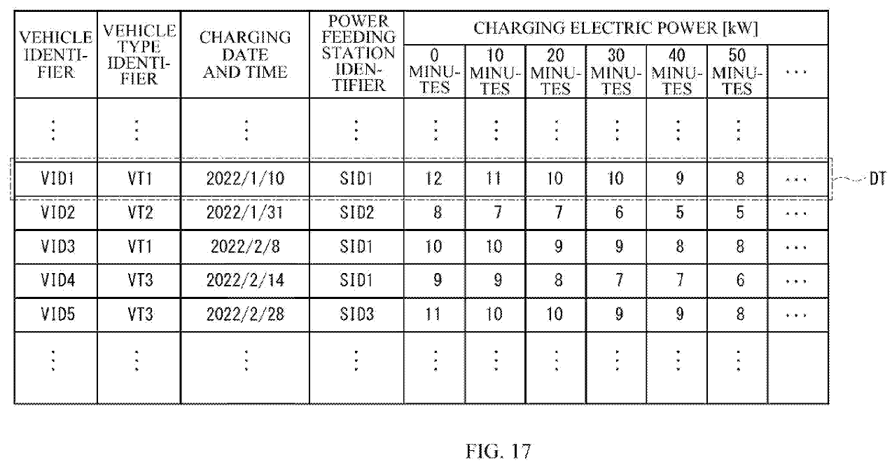

FIG. 17 illustrates an example of multiple pieces of charging data DT stored in the storage 140. The charging data DT may include a vehicle identifier for identification of a vehicle, the vehicle type identifier for identification of the vehicle type, the charging date and time when the vehicle has performed the charging operation, the power feeding station identifier of the power feeding station 10 that has fed power to the vehicle, and data regarding a temporal change in the charging electric power. Thus, the storage 140 may hold multiple pieces of charging data DT related to various vehicles.

The charging data acquisition unit 132 may acquire, out of the multiple pieces of charging data DT stored in the storage 140, pieces of charging data DT that include the same power feeding station identifier as the power feeding station identifier of the power feeding station 10 feeding power to the vehicle 79, and include the same vehicle type identifier as the vehicle type identifier of the vehicle 79. The charging data acquisition unit 132 may supply the acquired pieces of charging data DT to the approximate curve calculation unit 133.

The approximate curve calculation unit 133 may calculate respective approximate curves of the pieces of charging data DT acquired by the charging data acquisition unit 132, as with the approximate curve calculation unit 33 according to the first example embodiment.

The estimation unit 134 may estimate the time during which the power feeding station 10 is able to feed power (i.e., the power feedable time T), based on the approximate curves calculated by the approximate curve calculation unit 133, by using data on the received electric power supplied from the electric power sensor 22, as with the estimation unit 34 according to the first example embodiment.

The storage 140 may be a nonvolatile storage device. For example, the storage 140 may include a hard disk drive or a semiconductor memory. The storage 140 may hold multiple pieces of charging data DT.

Next, description is given of an operation example of the charging system 3 when the storage battery 21 of the vehicle 79 is charged based on electric power supplied from the power feeding station 10. This operation may be similar to the case in the first example embodiment (FIG. 4), and the following description is thus given with reference to FIG. 4.

First, for example, when a driver who drives the vehicle 79 sets the plug of the power feeding cable 100 into an inlet of the vehicle 79, the communicator 29 of the vehicle 79 may receive a power feeding station identifier by communicating with the power feeding device 13 of the power feeding station 10 (step S101). The communicator 29 may supply the power feeding station identifier to the processor 90.

Thereafter, the charging control unit 31 of the vehicle 79 may start the charging operation performed to the storage battery 21 of the storage battery unit 20 (step S102). Thus, direct-current electric power supplied from the power feeding station 10 may start to be stored in the storage battery 21 of the storage battery unit 20.

Thereafter, the electric power sensor 22 of the storage battery unit 20 may detect the charging electric power supplied to the storage battery 21 (step S103). The electric power sensor 22 may supply a detection result thus obtained to the processor 90.

Thereafter, the processor 90 may check whether the electric power sensor 22 has detected the charging electric power three times or more (step S104). If the electric power sensor 22 has not yet detected the charging electric power three times or more (“N” in step S104), the process may return to step S103. Thus, the processor 90 may repeat steps S103 and S104 until the electric power sensor 22 detects the charging electric power three times.

If the electric power sensor 22 has already detected the charging electric power three times or more in step S104 (“Y” in step S104), the processor 90 may check whether the server 110 has estimated the power feedable time T (step S105). If the server 110 has already estimated the power feedable time T (“Y” in step S105), the process may proceed to step S107.

If the server 110 has not yet estimated the power feedable time T in step S105 (“N” in step S105), the server 110 may perform an estimation process of estimating the power feedable time T, based on an instruction from the vehicle 79 given by the communication COM2 (step S106).

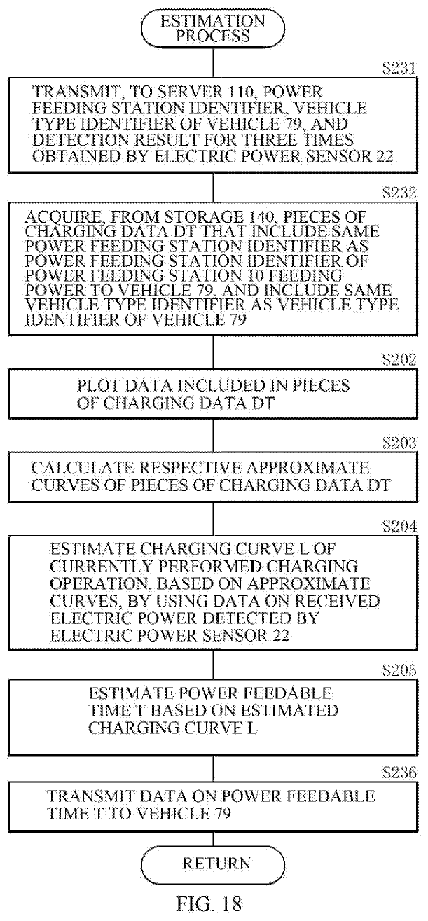

FIG. 18 illustrates an example of a subroutine of the estimation process of estimating the power feedable time T according to the example embodiment.

First, based on an instruction from the processor 90, the wireless communicator 81 of the vehicle 79 may transmit, to the server 110, the power feeding station identifier received in step S101, the vehicle type identifier of the vehicle 79, and the detection result for the three times obtained by the electric power sensor 22 in step S103, by performing the communication COM2 (step S231). The communicator 120 of the server 110 may receive such data, and supply the received data to the processor 130.

Thereafter, the charging data acquisition unit 132 of the processor 130 may acquire, from the storage 140, pieces of charging data DT that include the same power feeding station identifier as the power feeding station identifier, acquired in step S231, of the power feeding station 10 currently feeding power to the vehicle 79, and include the same vehicle type identifier as the vehicle type identifier of the vehicle 79 acquired in step S231, out of the stored multiple pieces of charging data DT (step S232).

Thereafter, the charging data acquisition unit 132 may plot the data on the charging electric power included in the pieces of charging data DT acquired in step S232 (step S202). The approximate curve calculation unit 133 may calculate respective approximate curves of the pieces of charging data DT plotted in step S202 (step S203). The estimation unit 134 may estimate the charging curve L of the currently performed charging operation, based on the approximate curves calculated by the approximate curve calculation unit 133, by using the data on the received electric power detected by the electric power sensor 22 and acquired in step S231 (step S204). The estimation unit 134 may estimate the power feedable time T, based on the charging curve L estimated in step S204 (step S205).

The communicator 120 of the server 110 may, based on an instruction from the processor 130, transmit data on the power feedable time T estimated in step S205 to the vehicle 79, by performing the communication COM2 (step S236). The wireless communicator 81 of the vehicle 79 may receive such data, and supply the received data to the processor 90.

This may be the end of the subroutine of the estimation process. For example, an unillustrated display device of the vehicle 79 may present the estimated power feedable time T to the driver.

Thereafter, as illustrated in FIG. 4, the charging control unit 31 may check whether charging is to be ended (step S107). If charging is not to be ended (“N” in step S107), the process may return to step S103.

If charging is to be ended in step S107 (“Y” in step S107), the charging data registration unit 135 may generate charging data DT related to the present charging operation (step S108). In one example, first, based on an instruction from the processor 90, the wireless communicator 81 of the vehicle 79 may transmit, to the server 110 via the communication COM2, the date and time when the present charging operation has been started, the power feeding station identifier received in step S101, and the data on the charging electric power for every 10 minutes detected in step S103. The communicator 120 of the server 110 may receive such information. The charging data registration unit 135 of the server 110 may generate charging data DT including the received information.

The charging data registration unit 135 may register the charging data DT in the storage 140 (step S109).

Thereafter, this process may end.

In this manner, in the charging system 3, the server 110 may estimate the power feedable time T by using the charging data DT on the multiple vehicles. This increases the number of pieces of the charging data DT to be used in estimating the power feedable time T, which makes it possible to enhance the estimation accuracy of the power feedable time T.

As described above, in the example embodiment, the server may estimate the power feedable time T by using the charging data DT on the multiple vehicles, which makes it possible to enhance the estimation accuracy of the power feedable time. Other effects may be similar to those in the first example embodiment.

In the third example embodiment, the server 110 may include the approximate curve calculation unit 133 and the estimation unit 134, but this is non-limiting. Alternatively, for example, the vehicle 79 may be configured to perform one or more of operations of the approximate curve calculation unit 133 and the estimation unit 134.

The modification examples of the first example embodiment may be applied to the charging system 3 according to the third example embodiment.

Although some example embodiments of the disclosure have been described in the foregoing by way of example with reference to the accompanying drawings, the disclosure is by no means limited to the embodiments described above. It should be appreciated that modifications and alterations may be made by persons skilled in the art without departing from the scope as defined by the appended claims. The disclosure is intended to include such modifications and alterations in so far as they fall within the scope of the appended claims or the equivalents thereof.

For example, in the foregoing example embodiments, the electric power sensor 22 may detect the received electric power at the intervals of five minutes in steps S103 and S104 of FIG. 4, but this is non-limiting. Alternatively, for example, the electric power sensor 22 may detect the received electric power at time intervals shorter than five minutes, or may detect the received electric power at time intervals longer than five minutes.

For example, in the foregoing example embodiments, the charging data DT may include the data on the charging electric power for every 10 minutes, but this is non-limiting. Alternatively, for example, the charging data DT may include data on charging electric power with time intervals shorter than 10 minutes, or may include data on charging electric power with time intervals longer than 10 minutes.

For example, in the foregoing example embodiments, the charging systems 1 and 3 (FIGS. 1 and 14) may feed power to one vehicle, but this is non-limiting. For example, the charging systems 1 and 3 may feed power to multiple vehicles, as with the charging system 2 (FIG. 11).

For example, in the foregoing example embodiments, the disclosure may be applied to a vehicle. Without being limited thereto, the disclosure may be applied to various apparatuses including a storage battery.

Each of the processor 30, the processor 70, the processor 90, and the processor 130 illustrated in FIGS. 2, 12, 15, and 16 is implementable by circuitry including at least one semiconductor integrated circuit such as at least one processor (e.g., a central processing unit (CPU)), at least one application specific integrated circuit (ASIC), and/or at least one field programmable gate array (FPGA). At least one processor is configurable, by reading instructions from at least one machine readable non-transitory tangible medium, to perform all or a part of functions of each of the processor 30, the processor 70, the processor 90, and the processor 130. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the nonvolatile memory may include a ROM and a NVRAM. The ASIC is an integrated circuit (IC) customized to perform, and the FPGA is an integrated circuit designed to be configured after manufacturing in order to perform, all or a part of the functions of each of the processor the processor 70, the processor 90, and the processor 130 illustrated in FIGS. 2, 12, 15, and 16.

1. A charging system comprising:
a charging control unit configured to control a charging operation performed from a power feeding system comprising a power storage device to a storage battery;
a detector configured to detect, multiple times, charging electric power supplied to the storage battery;
an acquisition unit configured to acquire pieces of charging data each comprising data indicating a temporal change in the charging electric power supplied from the power feeding system to the storage battery;
a calculation unit configured to calculate respective approximate curves of the pieces of charging data; and
an estimation unit configured to estimate a power feedable time during which the power feeding system is able to feed power, based on the approximate curves calculated based on the pieces of charging data, by using values of the charging electric power detected by the detector.

2. The charging system according to claim 1, wherein the estimation unit is configured to
estimate a charging curve indicating a change in the charging electric power, based on the approximate curves calculated based on the pieces of charging data, by using the values of the charging electric power detected by the detector,
estimate the power feedable time based on the charging curve, and
further estimate remaining storage battery power of the power storage device, based on the charging curve.

3. The charging system according to claim 1, wherein the pieces of charging data comprise data generated within a predetermined period.

4. The charging system according to claim 2, wherein the pieces of charging data comprise data generated within a predetermined period.

5. The charging system according to claim 1, wherein the pieces of charging data further comprise data indicating a temporal change in charging electric power supplied from the power feeding system to another storage battery that is different from the storage battery and is of a same type as the storage battery.

6. The charging system according to claim 2, wherein the pieces of charging data further comprise data indicating a temporal change in charging electric power supplied from the power feeding system to another storage battery that is different from the storage battery and is of a same type as the storage battery.

7. The charging system according to claim 1, further comprising:
a storage configured to hold the pieces of charging data; and
a registration unit configured to generate charging data based on the data indicating the temporal change in the charging electric power detected by the detector, and register the generated charging data in the storage.

8. The charging system according to claim 2, further comprising:
a storage configured to hold the pieces of charging data; and
a registration unit configured to generate charging data based on the data indicating the temporal change in the charging electric power detected by the detector, and register the generated charging data in the storage.

9. A charging system comprising:
a sensor configured to detect, multiple times, charging electric power supplied from a power feeding system comprising a power storage device to a storage battery; and
circuitry configured to
control a charging operation performed from the power feeding system to the storage battery,
acquire pieces of charging data each comprising data indicating a temporal change in the charging electric power supplied from the power feeding system to the storage battery,
calculate respective approximate curves of the pieces of charging data, and
estimate a power feedable time during which the power feeding system is able to feed power, based on the approximate curves calculated based on the pieces of charging data, by using values of the charging electric power detected by the detector.
